(19) United States
(12) Patent Application Publication
(10) Pub. No.: US 2025/0386723 A1
(43) Pub. Date: Dec. 18, 2025

(54) DISPLAY DEVICE AND METHOD FOR REPAIRING THE SAME

(71) Applicant: Samsung Display Co., LTD., Yongin-si (KR)

(72) Inventor: IN SOO PARK, Yongin-si (KR)

(21) Appl. No.: 19/018,677

(22) Filed: Jan. 13, 2025

(30) Foreign Application Priority Data
Jun. 18, 2024 (KR) 10-2024-0078685

(51) Int. Cl. H10K 71/00; G06F 1/16

(52) U.S. Cl. CPC H10K 71/861; G06F 1/1616; G06F 1/1656; G06F 1/1681

(57) ABSTRACT

A display device includes: a display module including a first non-folding region, a foldable region, and a second non-folding region arranged in a first direction; a first support part disposed below the first non-folding region; a second support part disposed below the second non-folding region; a plurality of hinges separated from each other and disposed below the foldable region and between the first support part and the second support part; and a plurality of hinge covers disposed below the hinges.

This application claims priority to Korean Patent Application No. 10-2024-0078685, filed on Jun. 18, 2024, and all the benefits accruing therefrom under 35 U.S.C. § 119, the content of which in its entirety is herein incorporated by reference.

### BACKGROUND

The present disclosure herein relates to a display device and a method for repairing the same.

An electronic apparatus which provides images to users, such as a smartphone, a digital camera, a laptop computer, a navigation unit, and a smart television includes a display device for displaying the images. The display device generates images and provides the images to users through a display screen.

With the technological development for the display device, various types of display devices are being developed. For example, a variety of flexible display devices, which are deformable into a curved form, foldable, or rollable, are being developed. The flexible display devices having diversely deformable shapes are easy to carry and improve user's convenience.

A foldable display device among the flexible display devices includes a display module which is folded with respect to a folding axis extending in one direction. The display module is folded or unfolded with respect to the folding axis. The foldable display device includes a hinge such that the display module is folded. The hinge defines the folding axis, and allows the display module to be folded with respect to the folding axis.

### SUMMARY

The present disclosure provides a display device which is easy to be repaired, and a method for repairing the same.

An embodiment of the invention provides a display device including: a display module including a first non-folding region, a foldable region, and a second non-folding region arranged in a first direction; a first support part disposed below the first non-folding region; a second support part disposed below the second non-folding region; a plurality of hinges separated from each other, and disposed below the foldable region and between the first support part and the second support part; and a plurality of hinge covers disposed below the hinges.

In an embodiment of the invention, a method for repairing a display device includes: preparing a display device which includes a display module including a first non-folding region, a foldable region, and a second non-folding region arranged in a first direction, a first support part disposed below the first non-folding region, a second support part disposed below the second non-folding region, a plurality of hinges disposed below the foldable region and between the first and second support parts and coupled to the first and second support parts, and a plurality of hinge covers disposed below the hinges and coupled to the hinges; folding the display device; separating the hinge covers from the hinges, and checking whether a defective hinge among the hinges exists; separating the defective hinge from the first and second support parts; coupling a normal hinge to the first and second support parts; and coupling a hinge cover separated from the defective hinge among the hinge covers to a rear surface of the normal hinge.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of a display device in an unfolded state according to an embodiment of the invention;

FIGS. 2 and 3 are views illustrating a state in which the display device illustrated in FIG. 1 is folded;

FIG. 4 exemplarily illustrates a cross-sectional view of an electronic panel of a display device according to an embodiment of the invention;

FIG. 5 exemplarily illustrates a cross-sectional view of the display panel illustrated in FIG. 4;

FIG. 6 is a plan view of the display panel illustrated in FIG. 5;

FIG. 7 exemplarily illustrates a cross-sectional view of an electronic panel corresponding to one pixel illustrated in FIG. 6;

FIG. 8 is a cross-sectional view of a display module corresponding to a cross section taken along line I-I′ illustrated in FIG. 7;

FIG. 9 is a perspective view of a support plate illustrated in FIG. 8;

FIG. 10 is an enlarged view of first region A1 illustrated in FIG. 9;

FIG. 11 is an exploded perspective view of the display device illustrated in FIG. 1;

FIG. 12 is an exploded perspective view of a folding set illustrated in FIG. 11;

FIGS. 13A and 13B are cross-sectional views taken along line II-II′ illustrated in FIG. 12;

FIGS. 14A and 14B are cross-sectional views taken along line III-III′ illustrated in FIG. 12;

FIGS. 15A, 15B, and 15C are cross-sectional views taken along line IV-IV′ illustrated in FIG. 12;

FIGS. 16 to 20 are views for describing a method for repairing a display device according to an embodiment of the invention;

FIG. 21 is a view illustrating an auxiliary cover covering the cover part illustrated in FIG. 12; and

FIGS. 22 and 23 are views illustrating an auxiliary cover coupled to a cover part.

### DETAILED DESCRIPTION

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thickness, the ratio, and the dimension of the elements are exaggerated for effective description of the technical contents.

The term “and/or” includes all combinations of one or more of the associated listed elements.

Although the terms “first”, “second”, etc., may be used to describe various elements, these elements should not be limited by these terms. These terms are only used to distinguish one element from another element. For example, a first element may be referred to as a second element, and similarly, a second element may also be referred to as a first element without departing from the scope of the invention. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, embodiments of the invention will be described with reference to the drawings.

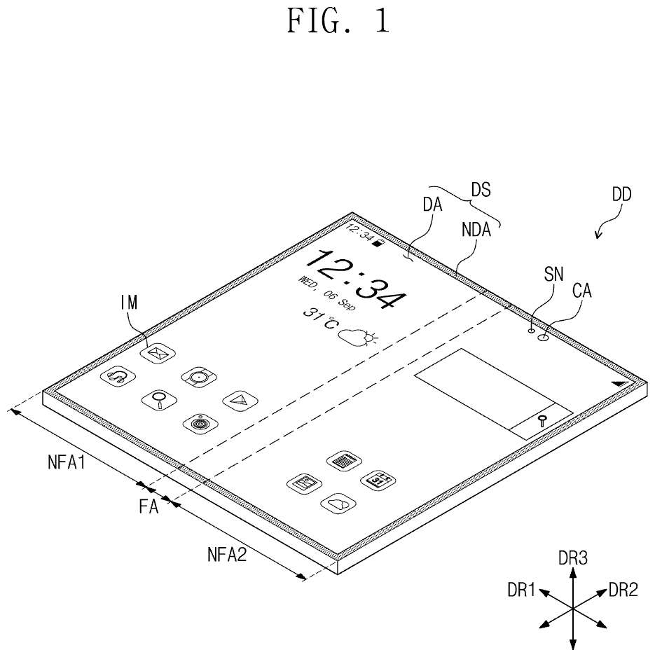

FIG. 1 is a perspective view of a display device in an unfolded state according to an embodiment of the invention.

Referring to FIG. 1, a display device DD according to an embodiment of the invention may have a quadrilateral shape which has sides extending in a first direction DR1 and sides extending in a second direction DR2 crossing the first direction DR1. However, the embodiment of the invention is not limited thereto, and the display device DD may have various shapes such as a circle and a polygon. The display device DD may be a flexible display device.

Hereinafter, a direction, which is substantially perpendicular to a plane defined by the first direction DR1 and the second direction DR2, is defined as a third direction DR3. Also, in this specification, the wording “when viewed on a plane” (i.e., in a plan view) may be defined as a state when viewed in the third direction DR3. The third direction DR3 is a thickness direction of the display device DD in an unfolded state.

The display device DD may include a foldable region FA and a plurality of non-folding regions NFA1 and NFA2. The non-folding regions NFA1 and NFA2 may include a first non-folding region NFA1 and a second non-folding region NFA2. The foldable region FA may be disposed between the first non-folding region NFA1 and the second non-folding region NFA2. The first non-folding region NFA1, the foldable region FA, and the second non-folding region NFA2 may be arranged in the first direction DR1 in the unfolded state.

One foldable region FA and two non-folding regions NFA1 and NFA2 are exemplarily illustrated, but the number of the foldable region FA and the number of the non-folding regions NFA1 and NFA2 are not limited thereto. For another example, the display device DD may include more than two non-folding regions and a plurality of foldable regions disposed with the non-folding regions therebetween.

An upper surface of the display device DD may be defined as a display surface DS, and the display surface DS may have a flat surface defined by the first direction DR1 and the second direction DR2. Images IM generated by the display device DD through the display surface DS may be provided to users.

The display surface DS may include a display region DA and a non-display region NDA around the display region DA. The display region DA may display images, and the non-display region NDA may not display images. The non-display region NDA may surround the display region DA and define a border of the display device DD printed in a predetermined color.

The display device DD may include at least one sensor SN and at least one camera CA. The sensor SN and the camera CA may be adjacent to the border of the display device DD. The sensor SN and the camera CA may be disposed in the display region DA adjacent to the non-display region NDA. The sensor SN and the camera CA may be disposed in the second non-folding region NFA2, but are not limited thereto. The sensor SN and the camera CA may be disposed in the first non-folding region NFA1 in another embodiment.

Light may pass through portions, of the display device DD, in which the sensor SN and the camera CA are disposed, and may be provided to the camera CA and the sensor SN. For example, the sensor SN may be a proximity sensor, but a type of sensor SN is not limited thereto. The camera CA may capture an external image. The sensor SN and the camera CA may each be provided in plurality.

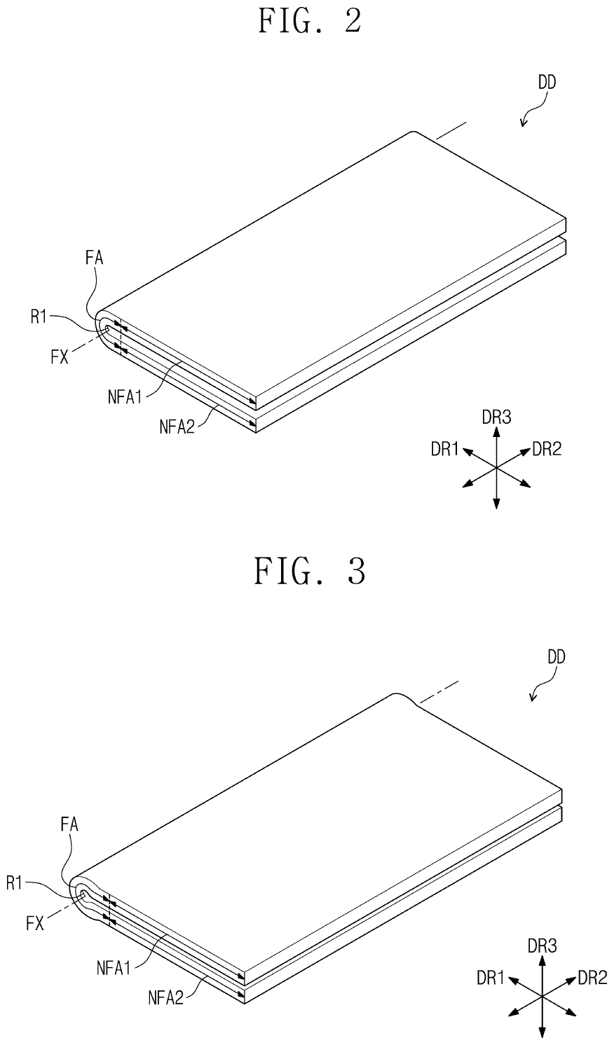

FIGS. 2 and 3 are views illustrating a state in which the display device illustrated in FIG. 1 is folded.

Referring to FIGS. 2 and 3, the display device DD may be a folding-type (foldable) display device DD which is folded or unfolded. For example, the display device DD may be folded such that the foldable region FA is bent with respect to a folding axis FX parallel to the second direction DR2.

When the display device DD is folded, the display device DD may be in-folded such that the first non-folding region NFA1 and the second non-folding region NFA2 face each other and the display surface DS is not exposed to the outside. However, the embodiment of the invention is not limited thereto. For another example, the display device DD may be out-folded with respect to the folding axis FX such that the display surface DS is exposed to the outside.

The foldable region FA may be bent so as to have a radius of curvature R1. As illustrated in FIG. 2, a distance between the first non-folding region NFA1 and the second non-folding region NFA2 may be substantially the same as two times the radius of curvature R1 (for example, a diameter). In this case, the display device DD may be folded into a U-shape.

However, as illustrated in FIG. 3, the distance between the first non-folding region NFA1 and the second non-folding region NFA2 is not limited thereto, and may be substantially smaller than two times the radius of curvature R1 in another embodiment. In this case, the display device DD may be folded into a dumbbell-like shape.

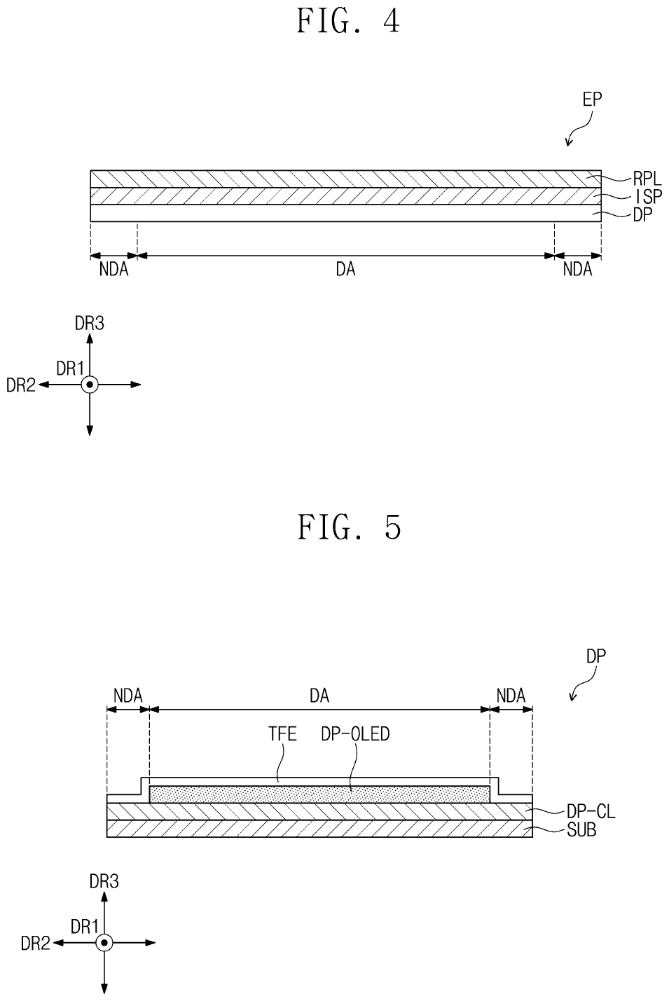

FIG. 4 exemplarily illustrates a cross-sectional view of an electronic panel of a display device according to an embodiment of the invention. FIG. 5 exemplarily illustrates a cross-sectional view of the display panel illustrated in FIG. 4.

For example, FIGS. 4 and 5 illustrate cross sections when viewed in the first direction DR1.

Referring to FIG. 4, the above-described display device DD may include an electronic panel EP illustrated in FIG. 4. The electronic panel EP may include a display panel DP, an input-sensing unit ISP disposed on the display panel DP, and an anti-reflection layer RPL disposed on the input-sensing unit ISP.

The display panel DP may be a flexible display panel. The display panel DP according to an embodiment of the invention may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, etc. Hereinafter, the display panel DP is described as an organic light-emitting display panel.

The input-sensing unit ISP may include a plurality of sensor units (not illustrated) for sensing an external input in a capacitive manner. The input-sensing unit ISP may be directly manufactured on the display panel DP when the display device DD is manufactured. However, an embodiment of the invention is not limited thereto. The input-sensing unit ISP may be manufactured as a panel separately from the display panel DP and then attached to the display panel DP via an adhesive layer in another embodiment.

The anti-reflection layer RPL may be directly manufactured on the input-sensing unit ISP when the display device DD is manufactured. However, an embodiment of the invention is not limited thereto. The anti-reflection layer RPL may be separately manufactured as a panel and then attached to the input-sensing unit ISP via an adhesive layer in another embodiment.

The anti-reflection layer RPL may be defined as an external light anti-reflection film. The anti-reflection layer RPL may reduce reflectance for external light which enters the display panel DP from above the display device DD.

Referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include glass or a flexible plastic material such as polyimide (“PI”). The display element layer DP-OLED may be disposed in the display region DA.

A plurality of pixels may be disposed on the circuit element layer DP-CL and the display element layer DP-OLED. The pixels may each include a transistor disposed on the circuit element layer DP-CL, and a light-emitting element disposed on the display element layer DP-OLED and connected to the transistor.

The thin-film encapsulation layer TFE may be disposed on the circuit element layer DP-CL so as to cover the display element layer DP-OLED. The thin-film encapsulation layer TFE may protect the pixels against moisture, oxygen, and external foreign substances.

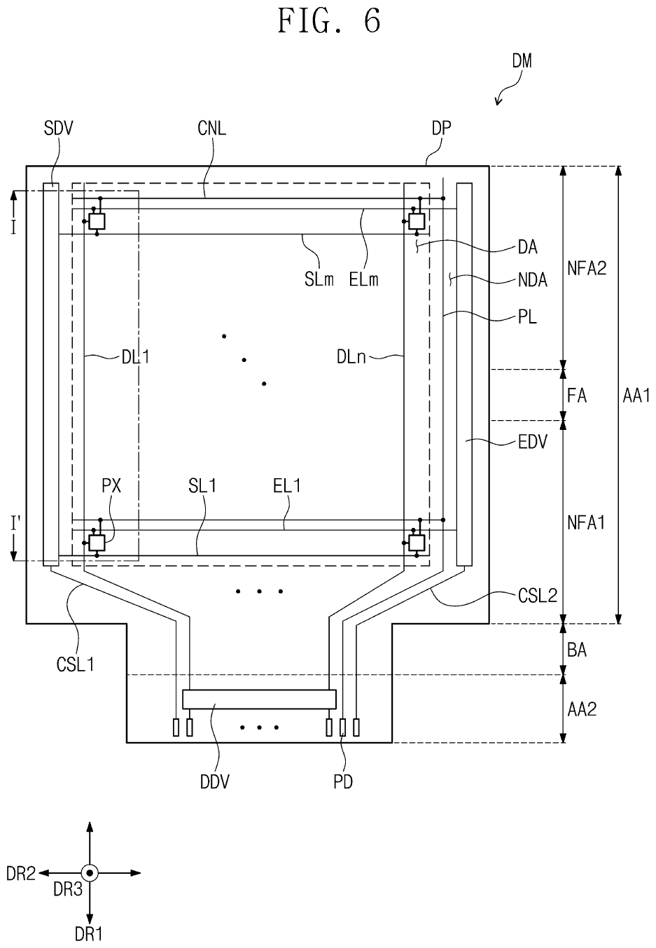

FIG. 6 is a plan view of the display panel illustrated in FIG. 5.

Referring to FIG. 6, the display device DD may include a display panel DP, a scan driver SDV, a data driver DDV, and a light-emitting driver EDV.

The display panel DP may include a first region AA1, a second region AA2, and a bending region BA between the first region AA1 and the second region AA2. The bending region BA may extend in the second direction DR2, and the first region AA1, the bending region BA, and the second region AA2 may be arranged in the first direction DR1 in an unfolded state.

The first region AA1 may include a display region DA and a non-display region NDA around the display region DA. The non-display region NDA may surround the display region DA. The display region DA may display images, and the non-display region NDA may not display images. The second region AA2 and the bending region BA may not display images.

When viewed in the second direction DR2, the first region AA1 may include a first non-folding region NFA1, a second non-folding region NFA2, and a foldable region FA between the first non-folding region NFA1 and the second non-folding region NFA2. The first and second non-folding regions NFA1 and NFA2, and the foldable region FA may correspond to the first and second non-folding regions NFA1 and NFA2, and the foldable region FA of the display device DD illustrated in FIG. 1, respectively.

The first region AA1 may be folded so as to be bent with respect to the above-described folding axis FX. For example, the display panel DP may be folded such that the foldable region FA of the first region AA1 is bent with respect to the above-described folding axis FX.

The display panel DP may include a plurality of pixels PX, a plurality of scan lines SL1 to SLm, a plurality of data lines DL1 to DLn, a plurality of light-emitting lines EL1 to ELm, first and second control lines CSL1 and CSL2, a power supply line PL, a plurality of connection lines CNL, and a plurality of pads PD. m and n are natural numbers. The pixels PX may be disposed in the display region DA and be connected to the scan lines SL1 to SLm, the data lines DL1 to DLn, and the light-emitting lines EL1 to ELm.

The scan driver SDV and the light-emitting driver EDV may be disposed in the non-display region NDA. The scan driver SDV and the light-emitting driver EDV may be disposed in the non-display region NDA adjacent to each of opposite sides, of the first region AA1, which are opposed to each other in the second direction DR2. The data driver DDV may be disposed in the second region AA2. The data driver DDV may be manufactured in a form of an integrated circuit chip and be mounted on the second region AA2.

Although not illustrated, the bending region BA may be bent, and the second region AA2 may be disposed below the first region AA1. Accordingly, when the bending region BA is bent, the data driver DDV is disposed below the first region AA1, and may thus be invisible from the outside.

The scan lines SL1 to SLm may extend in the second direction DR2 to be connected to the scan driver SDV. The data lines DL1 to DLn may extend in the first direction DR1 to be connected to the data driver DDV via the bending region BA. The data driver DDV may be connected to the pixels PX via the data lines DL1 to DLn. The light-emitting lines EL1 to ELm may extend in the second direction DR2 to be connected to the light-emitting driver EDV.

A power supply line PL may extend in the first direction DR1 and be disposed in the non-display region NDA. The power supply line PL may be disposed between the display region DA and the light-emitting driver EDV. The power supply line PL may extend to the second region AA2 via the bending region BA. When viewed on a plane (i.e., in a plan view), the power supply line PL may extend toward a lower end of the second region AA2. The power supply line PL may receive a driving voltage.

The connection lines CNL may extend in the second direction DR2 and be arranged in the first direction DR1. The connection lines CNL may be connected to the power supply line PL and the pixels PX. The driving voltage may be applied to the pixels PX via the power supply line PL and the connection lines CNL which are connected to each other.

The first control line CSL1 may be connected to the scan driver SDV and extend toward the lower end of the second region AA2 via the bending region BA. The second control line CSL2 may be connected to the light-emitting driver EDV and extend toward the lower end of the second region AA2 via the bending region BA. The data driver DDV may be disposed between the first control line CSL1 and the second control line CSL2.

When viewed on a plane (i.e., in a plan view), pads PD may be disposed adjacent to the lower end of the second region AA2. The data driver DDV, the power supply line PL, the first control line CSL1, and the second control line CSL2 may be connected to the pads PD.

The data lines DL1 to DLn may be connected to the corresponding pads PD via the data driver DDV. For example, the data lines DL1 to DLn may be connected to the data driver DDV, and the data driver DDV may be connected to the pads PD corresponding to the data lines DL1 to DLn, respectively.

Although not illustrated, a printed circuit board may be connected to the pads PD, and a timing controller and a voltage generator may be disposed on the printed circuit board. The timing controller may be manufactured as an integrated circuit chip and be mounted on the printed circuit board. The timing controller and the voltage generator may be connected to the pads PD via the printed circuit board.

The timing controller may control operations of the scan driver SDV, the data driver DDV, and the light-emitting driver EDV. The timing controller may generate a scan control signal, a data control signal, and a light-emitting control signal in response to control signals received from the outside. The voltage generator may generate a driving voltage so as to be applied to the pixels PX.

The scan control signal may be provided to the scan driver SDV via the first control line CSL1. The light-emitting control signal may be provided to the light-emitting driver EDV via the second control line CSL2. The data control signal may be provided to the data driver DDV. The timing controller may receive image signals from the outside, convert data formats of the image signals so as to meet interface specifications of the data driver DDV, and provide the converted signals to the data driver DDV.

The scan driver SDV may generate a plurality of scan signals in response to a scan control signal. The scan signals may be applied to the pixels PX via the scan lines SL1 to SLm. The scan signals may be sequentially applied to the pixels PX.

The data driver DDV may generate a plurality of data voltages corresponding to image signals in response to a data control signal. The data voltages may be applied to the pixels PX via the data lines DL1 to DLn. The light-emitting driver EDV may generate a plurality of light-emitting signals in response to a light-emitting control signal. The light-emitting signals may be applied to the pixels PX via the light-emitting lines EL1 to ELm.

The pixels PX may receive the data voltages in response to the scan signals. The pixels PX may display images by emitting light having a luminance corresponding to the data voltages in response to the light-emitting signals. A light-emitting time of the pixels PX may be controlled by the light-emitting signals.

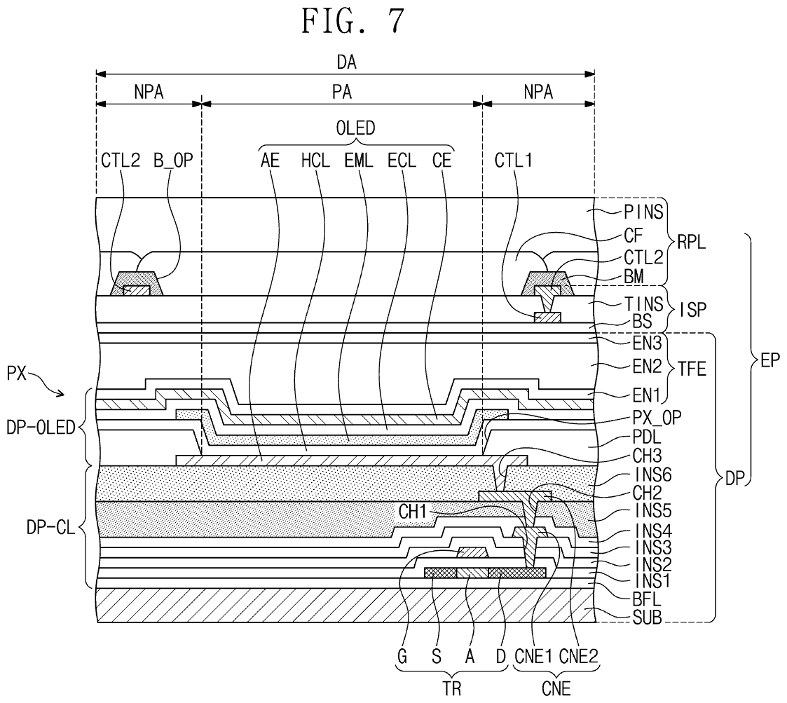

FIG. 7 exemplarily illustrates a cross-sectional view of an electronic panel corresponding to one pixel illustrated in FIG. 6.

Referring to FIG. 7, the pixel PX may include a transistor TR and a light-emitting element OLED. The light-emitting element OLED may include a first electrode AE (or an anode), a second electrode CE (or a cathode), a hole control layer HCL, an electron control layer ECL, and a light-emitting layer EML.

The transistor TR and the light-emitting element OLED may be disposed on a substrate SUB. One transistor TR is exemplarily illustrated in the drawing, but substantially, the pixel PX may include a plurality of transistors and at least one capacitor for driving the light-emitting element OLED.

The display region DA may include a light-emitting region PA corresponding to each of the pixels PX, and a non-light-emitting region NPA around the light-emitting region PA. The light-emitting element OLED may be disposed in the light-emitting region PA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or a metal oxide.

The semiconductor pattern may be doped with an N-type dopant or a P-type dopant. The semiconductor pattern may include a highly-doped region and a lightly-doped region. The highly-doped region may have conductivity higher than conductivity of the lightly-doped region, and substantially serve as a source electrode and a drain electrode of the transistor TR. The lightly-doped region may substantially correspond to an active (or a channel) of the transistor TR.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 which connect the transistor TR and the light-emitting element OLED. The first connection electrode CNE1 may be disposed on the third insulating layer INS3 and connected to the drain D via a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 via a second contact hole CH2 defined in the fourth and fifth insulating layers INS4 and INS5.

A sixth insulating layer INS6 may be disposed on the second connection electrode CNE2. The layers ranging from the buffer layer BFL to the sixth insulating layer INS6 may be defined as a circuit element layer DP-CL. The first insulating layer INS1 to the sixth insulating layer INS6 may each be an inorganic layer or an organic layer.

The first electrode AE may be disposed on the sixth insulating layer INS6. The first electrode AE may be connected to the second connection electrode CNE2 via a third contact hole CH3 defined in the sixth insulating layer INS6. A pixel-defining film PDL, in which an opening PX_OP for exposing a predetermined portion of the first electrode AE is defined, may be disposed on the first electrode AE and the sixth insulating layer INS6.

The hole control layer HCL may be disposed on the first electrode AE and the pixel-defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light having one color of red, green, or blue.

The electron control layer ECL may be disposed on the light-emitting layer EML and the hole control layer HCL. The electron control layer ECL may include an electron transport layer and an electron injection layer. The hole control layer HCL and the electron control layer ECL may be disposed in the light-emitting region PA and the non-light-emitting region NPA in common.

The second electrode CE may be disposed on the electron control layer ECL. The second electrode CE may be disposed in the pixels PX in common. The layer, on which the light-emitting element OLED is disposed, may be defined as a display element layer DP-OLED.

A thin-film encapsulation layer TFE may be disposed on the second electrode CE to cover the pixel PX. The thin-film encapsulation layer TFE may include a first encapsulation layer EN1 disposed on the second electrode CE and a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer, and protect the pixel PX against moisture/oxygen. The second encapsulation layer EN2 may include an organic insulating layer, and protect the pixel PX against foreign substances such as dust particles.

A first voltage may be applied to the first electrode AE through the transistor TR, and a second voltage having a level lower than a level of the first voltage may be applied to the second electrode CE. Holes and electrons injected into the light-emitting layer EML are combined to form excitons, and the excitons transition to a ground state, so that the light-emitting element OLED may emit light.

The layers ranging from the substrate SUB to the thin-film encapsulation layer TFE may be defined as a display panel DP. An input-sensing unit ISP may be disposed on the thin-film encapsulation layer TFE. The input-sensing unit ISP may be manufactured directly on an upper surface of the thin-film encapsulation layer TFE.

A base layer BS may be disposed on the thin-film encapsulation layer TFE. The base layer BS may include an inorganic insulating layer. At least one inorganic insulating layer may be provided on the thin-film encapsulation layer TFE as the base layer BS.

The input-sensing unit ISP may include a first conductive pattern CTL1 and a second conductive pattern CTL2 disposed on the first conductive pattern CTL1. The first conductive pattern CTL1 may be disposed on the base layer BS. An insulating layer TINS may be disposed on the base layer BS so as to cover the first conductive pattern CTL1. The insulating layer TINS may include an inorganic insulating layer or an organic insulating layer. The second conductive pattern CTL2 may be disposed on the insulating layer TINS.

The first and second conductive patterns CTL1 and CTL2 may overlap the non-light-emitting region NPA. Although not illustrated, the first and second conductive patterns CTL1 and CTL2 may be disposed on the non-light-emitting region NPA between the light-emitting regions PA, and have a mesh shape.

The first and second conductive patterns CTL1 and CTL2 may form sensors of the above-described input-sensing unit ISP. For example, the first and second conductive patterns CTL1 and CTL2 having a mesh shape may be separated from each other in a predetermined region, and form the sensors. A portion of the second conductive pattern CTL2 may be connected to the first conductive pattern CTL1.

An anti-reflection layer RPL may be disposed on the second conductive pattern CTL2. The anti-reflection layer RPL may include a black matrix BM and a plurality of color filters CF. The black matrix BM may overlap the non-light-emitting region NPA and the color filters CF may overlap the light-emitting regions PA, respectively.

The black matrix BM may be disposed on the insulating layer TINS so as to cover the second conductive pattern CTL2. An opening B_OP overlapping the light-emitting region PA and the opening PX_OP may be defined in the black matrix BM. The black matrix BM may absorb and block light. The width of the opening B_OP may be greater than the width of the opening PX_OP.

The color filters CF may be disposed on the insulating layer TINS and the black matrix BM. The color filters CF may be disposed in the openings B_OP, respectively. A planarization insulating layer PINS may be disposed on the color filters CF. The planarization insulating layer PINS may provide a flat upper surface.

When external light propagating toward the display panel DP is reflected at the display panel DP and is re-provided to an external user, the external light may be viewed by the user as if reflected from a mirror. In order to prevent the above-described phenomenon, the anti-reflection layer RPL may include, for example, the color filters CF which display the same colors as colors of the pixels PX of the display panel DP. The color filters CF may filter external light with the same colors as the colors of the pixels PX. In this case, the external light may be invisible to a user.

However, the embodiment of the invention is not limited thereto, and the anti-reflection layer RPL may include a polarization film for reducing reflectance for external light in another embodiment. The polarization film may be separately manufactured and be attached to the input-sensing unit ISP via an adhesive layer. The polarization film may include a retarder and/or a polarizer.

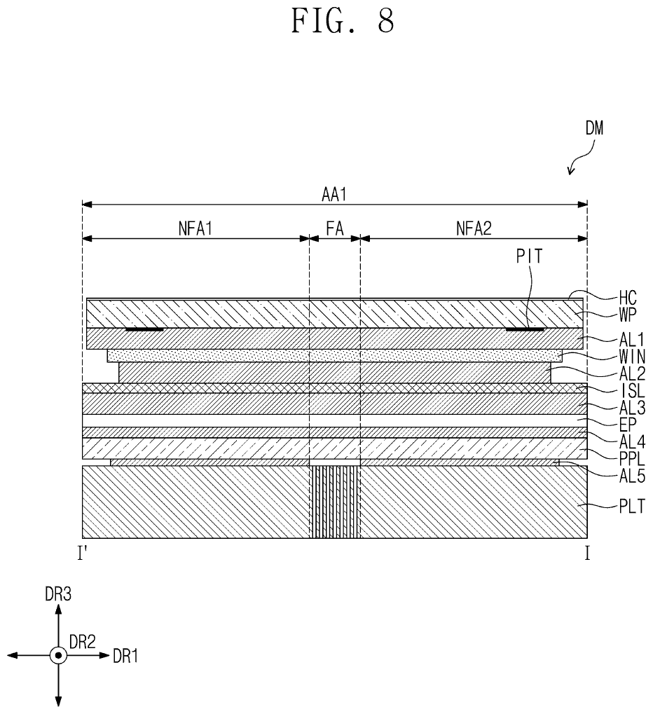

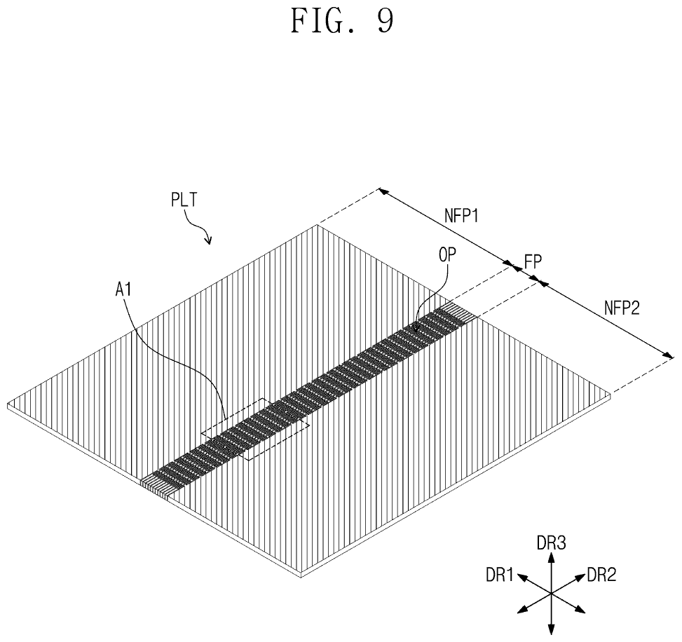

FIG. 8 is a cross-sectional view of a display module corresponding to a cross section taken along line I-I′ illustrated in FIG. 7.

Referring to FIG. 8, the above-described display device DD may include a display module DM illustrated in FIG. 8. The display module DM may include a hard coating layer HC, a printed layer PIT, a window WIN, a window protective layer WP, an impact absorbing layer ISL, an electronic panel EP, a panel protective layer PPL, a support plate PLT, and first to fifth adhesive layers AL1 to AL5.

The display module DM may be a flexible display module. The display module DM may include a first non-folding region NFA1, a foldable region FA, and a second non-folding region NFA2. The display module DM may be folded such that the foldable region FA is folded with respect to the above-described folding axis FX.

The window WIN may be disposed on the impact absorbing layer ISL. The window WIN may protect the electronic panel EP against external scratches. The window WIN may have an optically transparent property. The window WIN may include glass. However, an embodiment of the invention is not limited thereto, and the window WIN may include a synthetic resin film in another embodiment.

The window WIN may have a single- or multi-layered structure. For example, the window WIN may include a plurality of synthetic resin films bonded with an adhesive, or may include a glass substrate and a synthetic resin film bonded with an adhesive.

The window protective layer WP may be disposed on the window WIN. The window protective layer WP may include a flexible plastic material such as polyimide or polyethylene terephthalate. The hard coating layer HC may be disposed on an upper surface of the window protective layer WP.

The printed layer PIT may be disposed on a lower surface of the window protective layer WP. The printed layer PIT may be black, but a color of the printed layer PIT is not limited thereto. The printed layer PIT may be adjacent to a border of the window protective layer WP in another embodiment.

The impact absorbing layer ISL may be disposed on the electronic panel EP. The impact absorbing layer ISL absorbs an external impact applied from above the display device DD toward the electronic panel EP, and may thus protect the electronic panel EP. The impact absorbing layer ISL may be manufactured in a form of a stretched film.

The impact absorbing layer ISL may include a flexible plastic material. The flexible plastic material may be defined as a synthetic resin film. For example, the impact absorbing layer ISL may include a flexible plastic material such as polyimide (PI) or polyethylene terephthalate (“PET”).

The panel protective layer PPL may be disposed below the electronic panel EP. The panel protective layer PPL may be disposed below the display panel DP. The panel protective layer PPL may protect a lower part of the display panel DP. The panel protective layer PPL may include a flexible plastic material. For example, the panel protective layer PPL may include polyethylene terephthalate (PET).

The support plate PLT may be disposed below the panel protective layer PPL and support the electronic panel EP. The support plate PLT may include a non-metallic material. For example, the support plate PLT may include a reinforced fiber composite material. The reinforced fiber composite material may be a carbon fiber reinforced plastic (“CFRP”) or a glass fiber reinforced plastic (“GFRP”).

The support plate PLT includes the reinforced fiber composite material, and may thus have lightweight. The support plate PLT according to an embodiment includes the reinforced fiber composite material, and may thus have not only a lighter weight than a metal support plate made of a metal material, but also have modulus and strength similar to modulus and strength of the metal support plate.

The support plate PLT includes the reinforced fiber composite material, and thus shape processing of the support plate PLT may be easily performed compared to shape processing of the metal support plate. For example, the support plate PLT including the reinforced fiber composite material may be more easily processed through a laser process or micro blast process.

A plurality of openings OP may be defined in a portion of the support plate PLT overlapping the foldable region FA. The openings OP may be formed passing through portions of the support plate PLT in the third direction DR3. The openings OP may be formed through the above-described laser process or micro blast process.

The first adhesive layer AL1 may be disposed between the window protective layer WP and the window WIN. The window protective layer WP and the window WIN may be bonded to each other via the first adhesive layer AL1. The first adhesive layer AL1 may cover the printed layer PIT.

The second adhesive layer AL2 may be disposed between the window WIN and the impact absorbing layer ISL. The window WIN and the impact absorbing layer ISL may be bonded to each other via the second adhesive layer AL2.

The third adhesive layer AL3 may be disposed between the impact absorbing layer ISL and the electronic panel EP. The impact absorbing layer ISL and the electronic panel EP may be bonded to each other via the third adhesive layer AL3.

The fourth adhesive layer AL4 may be disposed between the electronic panel EP and the panel protective layer PPL. The electronic panel EP and the panel protective layer PPL may be bonded to each other via the fourth adhesive layer AL4.

The fifth adhesive layer AL5 may be disposed between the panel protective layer PPL and the support plate PLT. The panel protective layer PPL and the support plate PLT may be bonded to each other via the fifth adhesive layer AL5.

The first to fifth adhesive layers AL1 to AL5 may include a transparent adhesive such as a pressure sensitive adhesive (“PSA”) or an optically clear adhesive (“OCA”), but a type of adhesive is not limited thereto.

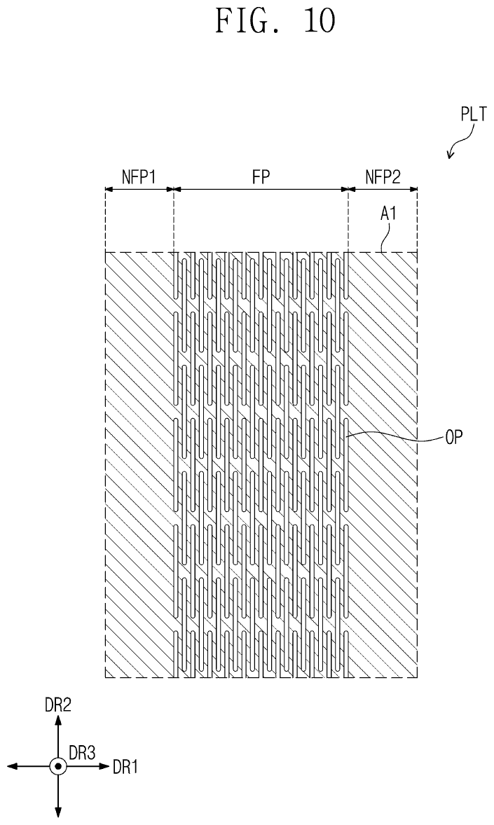

FIG. 9 is a perspective view of a support plate illustrated in FIG. 8 in an unfolded state. FIG. 10 is an enlarged view of first region A1 illustrated in FIG. 9.

Referring to FIGS. 9 and 10, the support plate PLT may include a first non-folding part NFP1, a folding part FP, and a second non-folding part NFP2. The folding part FP may be disposed between the first non-folding part NFP1 and the second non-folding part NFP2. When viewed on a plane (i.e., in a plan view), the first non-folding part NFP1 may overlap the first non-folding region NFA1, the folding part FP may overlap the foldable region FA, and the second non-folding part NFP2 may overlap the second non-folding region NFA2.

A plurality of openings OP may be defined in the folding part FP to form a grid pattern. The openings OP may be arranged in a predetermined rule. Since the openings OP are defined in the folding part FP, an area of the folding part FP is decreased, and thus the folding part FP may have reduced rigidity. When the openings OP are defined in the folding part FP, flexibility of the folding part FP may be more enhanced than that when the openings OP are not defined in the folding part FP. Accordingly, the folding part FP may be more easily bent.

Referring to FIG. 10, the openings OP may be arranged in the first direction DR1 and the second direction DR2. The openings OP may extend longer in the second direction DR2 than in the first direction DR1. For example, the openings OP arranged in an h-th column and the openings OP arranged in an (h+1)-th column may be disposed so as to be offset from each other. h is a natural number, and a column direction may correspond to the second direction DR2.

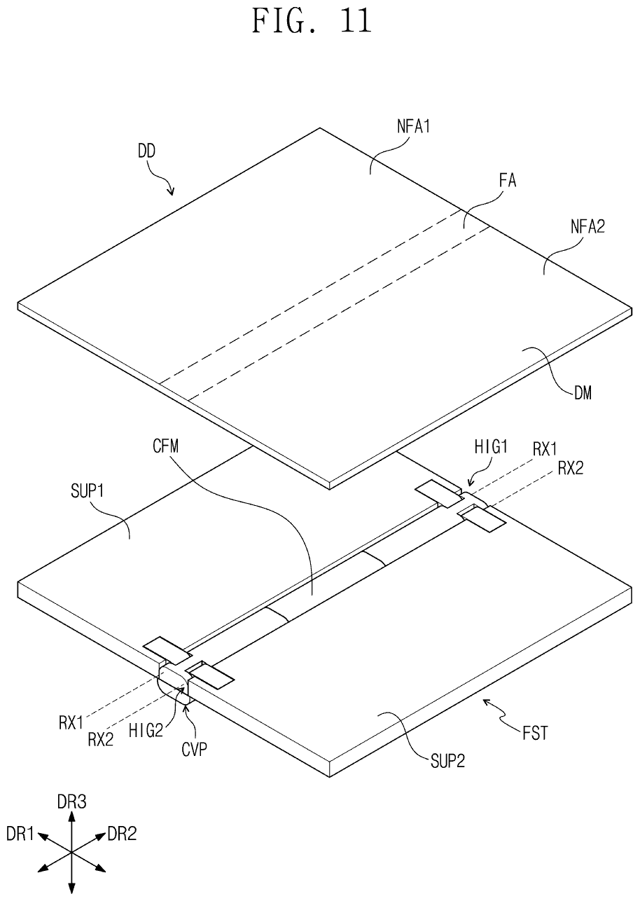

FIG. 11 is an exploded perspective view of the display device illustrated in FIG. 1.

Referring to FIG. 11, the display device DD may include a display module DM and a folding set FST disposed below the display module DM. The folding set FST may support the display module DM below the display module DM, and allow the display module DM to be folded.

The folding set FST may include a first support part SUP1, a second support part SUP2, a plurality of hinges HIG1 and HIG2, a central frame CFM, and a cover part CVP. The first support part SUP1 and the second support part SUP2 may be spaced apart from each other in the first direction DR1. The first direction DR1 may be defined as a horizontal direction.

The first support part SUP1 may be disposed below the first non-folding region NFA1, and may overlap the first non-folding region NFA1 when viewed on a plane (i.e., in a plan view). The first support part SUP1 may support the first non-folding region NFA1 below the first non-folding region NFA1.

The second support part SUP2 may be disposed below the second non-folding region NFA2, and may overlap the second non-folding region NFA2 when viewed on a plane (i.e., in a plan view). The second support part SUP2 may support the second non-folding region NFA2 below the second non-folding region NFA2.

The hinges HIG1 and HIG2, and the central frame CFM may be disposed below the foldable region FA. The hinges HIG1 and HIG2, and the central frame CFM may be disposed between the first support part SUP1 and the second support part SUP2. The hinges HIG1 and HIG2, and the central frame CFM may be arranged in the second direction DR2. The hinges HIG1 and HIG2 may be separated from each other in the second direction DR2.

The hinges HIG1 and HIG2 may include a first hinge HIG1 and a second hinge HIG2. The first hinge HIG1 and the second hinge HIG2 may be spaced apart from each other in the second direction DR2. The central frame CFM may be disposed between the first hinge HIG1 and the second hinge HIG2.

The first hinge HIG1 and the second hinge HIG2 may define biaxial rotation axes RX1 and RX2 parallel to each other and extending in the second direction DR2. The biaxial rotation axes RX1 and RX2 may substantially correspond to the above-described folding axis FX. The biaxial rotation axes RX1 and RX2 may include a first rotation axis RX1 adjacent to the first support part SUP1, and a second rotation axis RX2 adjacent to the second support part SUP2.

The first hinge HIG1 and the second hinge HIG2 may be adjacent to opposite sides, of the first and second support parts SUP1 and SUP2, opposed to each other in the second direction DR2. The first hinge HIG1 and the second hinge HIG2 may be coupled to the first support part SUP1 and the second support part SUP2. The central frame CFM may be coupled to the first hinge HIG1 and the second hinge HIG2.

The first hinge HIG1 and the second hinge HIG2 may rotate the first support part SUP1 and the second support part SUP2 with respect to the biaxial rotation axes RX1 and RX2. The first hinge HIG1 and the second hinge HIG2 may rotate the first support part SUP1 with respect to the first rotation axis RX1. The first hinge HIG1 and the second hinge HIG2 may rotate the second support part SUP2 with respect to the second rotation axis RX2.

When the first hinge HIG1 and the second hinge HIG2 rotate the first support part SUP1 and the second support part SUP2 with respect to the biaxial rotation axes RX1 and RX2, the display module DM may be folded by the first support part SUP1 and the second support part SUP2.

Although not illustrated, the display module DM may be attached to the first and second support parts SUP1 and SUP2 via an adhesive layer.

The cover part CVP may be disposed below the first and second hinges HIG1 and HIG2, and the central frame CFM. The cover part CVP may be coupled to the first and second hinges HIG1 and HIG2, and the central frame CFM.

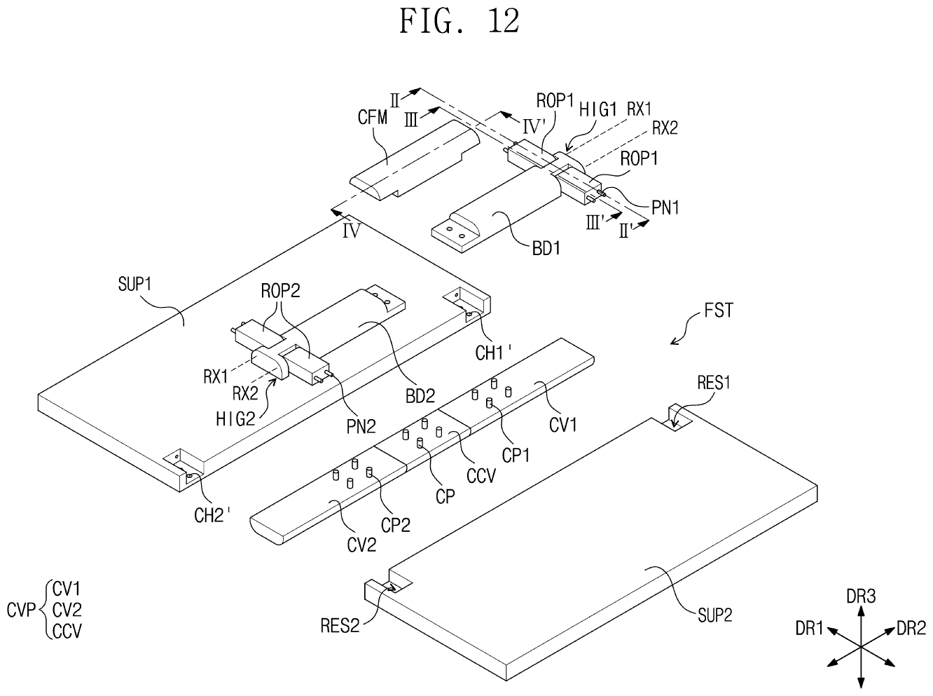

FIG. 12 is an exploded perspective view of the folding set illustrated in FIG. 11.

Referring to FIG. 12, the first and second hinges HIG1 and HIG2 may have a shape symmetrical to each other with respect to a plane (i.e., plane defined by the first and third direction DR1 and DR2), which is between the first hinge HIG1 and the second hinge HIG2 and parallel to the first direction DR1 and perpendicular to the second direction DR2. The first hinge HIG1 may have the substantially same configuration as a configuration of the second hinge HIG2.

The first hinge HIG1 may include a first main body BD1 and a plurality of first rotating parts ROP1. The first main body BD1 may extend in the second direction DR2, and be disposed between the first support part SUP1 and the second support part SUP2.

The first rotating parts ROP1 may extend in the first direction DR1, and be rotatably coupled to the first main body BD1. The first rotating parts ROP1 may each be rotatably coupled to opposite sides, of the first main body BD1, opposed to each other in the first direction DR1. The first rotating parts ROP1 may be adjacent to the other side, of the first main body BD1, opposed to one side of the first main body BD1 facing the central frame CFM in the first direction DR1.

First recessed portions RES1 may be defined on upper surfaces of the first and second support parts SUP1 and SUP2 adjacent to the first rotating parts ROP1. The first rotating parts ROP1 may each be disposed in the first recessed portions RES1.

The first hinge HIG1 may include a plurality of first coupling pins PN1 extending in the first direction DR1 from the first rotating parts ROP1 toward the first support part SUP1 and the second support part SUP2. An upper surface, of the first main body BD1, adjacent to one side of the first main body BD1 may be recessed downward.

The second hinge HIG2 may include a second main body BD2 and a plurality of second rotating parts ROP2. The second main body BD2 may extend in the second direction DR2, and be disposed between the first support part SUP1 and the second support part SUP2.

The second rotating parts ROP2 may extend in the first direction DR1, and be rotatably coupled to the second main body BD2. The second rotating parts ROP2 may each be rotatably coupled to opposite sides, of the second main body BD2, opposed to each other in the first direction DR1. The second rotating parts ROP2 may be adjacent to the other side, of the second main body BD2, opposed to one side of the second main body BD2 facing the central frame CFM in the first direction DR1.

Second recessed portions RES2 may be defined on the upper surfaces of the first and second support parts SUP1 and SUP2 adjacent to the second rotating parts ROP2. The second rotating parts ROP2 may each be disposed in the second recessed portions RES2.

The second hinge HIG2 may include a plurality of second coupling pins PN2 extending in the first direction DR1 from the second rotating parts ROP2 toward the first support part SUP1 and the second support part SUP2. An upper surface, of the second main body BD2, adjacent to one side of the second main body BD2 may be recessed downward.

A lower surface of the central frame CFM adjacent to the first main body BD1 may be recessed upward. Additionally, a lower surface of the central frame CFM adjacent to the second main body BD2 may be recessed upward.

The cover part CVP may include a plurality of hinge covers CV1 and CV2, and a central cover CCV. The hinge covers CV1 and CV2 may be disposed below the hinges HIG1 and HIG2, and the central cover CCV may be disposed below the central frame CFM. The hinge covers CV1 and CV2 may be in a state of being separated from each other. The hinge covers CV1 and CV2 may be disposed below the hinges HIG1 and HIG2 respectively so as to one-to-one correspond to (e.g., cover) the hinges HIG1 and HIG2.

The hinge covers CV1 and CV2 may include a first hinge cover CV1 disposed below the first hinge HIG1, and a second hinge cover CV2 disposed below the second hinge HIG2. The first hinge cover CV1 and the second hinge cover CV2 may be separated from each other to be spaced apart in the second direction DR2. The central cover CCV may be disposed between the first hinge cover CV1 and the second hinge cover CV2.

The cover part CVP may include a plurality of first coupling pins CP1 extending along the upward direction from an upper surface of the first hinge cover CV1, and a plurality of second coupling pins CP2 extending along the upward direction from an upper surface of the second hinge cover CV2. Additionally, the cover part CVP may include a plurality of coupling pins CP extending along the upward direction from an upper surface of the central cover CCV.

First fastening holes CH1′ may be defined in portions of the first and second support parts SUP1 and SUP2 each having the first recessed portion RES1 defined therein. Second fastening holes CH2′ may be defined in portions of the first and second support parts SUP1 and SUP2 each having the second recessed portion RES2 defined therein.

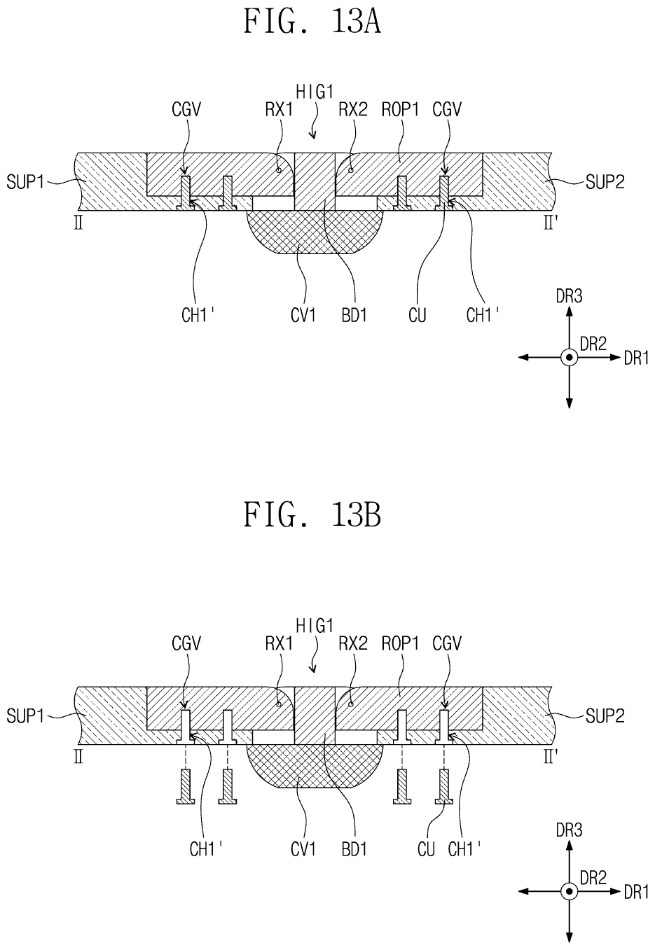

FIGS. 13A and 13B are cross-sectional views taken along line II-II′ illustrated in FIG. 12.

For example, FIG. 13A illustrates a state in which the first and second support parts SUP1 and SUP2 are coupled to the first hinge HIG1, and FIG. 13B illustrates a state in which the first and second support parts SUP1 and SUP2, and the first hinge HIG1 are separated from each other.

Referring to FIGS. 12 and 13A, the first hinge HIG1 may be coupled to the first support part SUP1 and the second support part SUP2. For example, the first rotating parts ROP1 may be disposed in the first recessed portions RES1 to be coupled to the first support part SUP1 and the second support part SUP2.

The first rotating parts ROP1 may be coupled to the first support part SUP1 and the second support part SUP2 by a plurality of fastening units CU. For example, the fastening units CU may be screws. Fastening grooves CGV overlapping the first fastening holes CH1′ in a plan view in an unfolded state may be defined on lower surfaces of the first rotating parts ROP1. The fastening units CU are inserted into the first fastening holes CH1′ and the fastening grooves CGV such that the first rotating parts ROP1 may be coupled to the first support part SUP1 and the second support part SUP2.

Although not illustrated, the coupling structure of the second hinge HIG2, and the first and second support parts SUP1 and SUP2 may be the same as or similar to the coupling structure of the first hinge HIG1, and the first and second support parts SUP1 and SUP2. For example, the second rotating parts ROP2 may be disposed in the second recessed portions RES2. Next, the fastening units CU are inserted into the second fastening holes CH2′, and the fastening grooves, which are defined on the lower surfaces of the second rotating parts ROP2 so as to overlap the second fastening holes CH2′ in a plan view in an unfolded state, such that the second hinge HIG2, and the first and second support parts SUP1 and SUP2 may be coupled to each other.

Referring to FIGS. 13A and 13B, when the fastening units CU are separated from the first rotating parts ROP1, and the first and second support parts SUP1 and SUP2, the first rotating parts ROP1, and the first and second support parts SUP1 and SUP2 may be separated from each other.

Although not illustrated, when the fastening units CU are separated from the second rotating parts ROP2, and the first and second support parts SUP1 and SUP2, the second rotating parts ROP2 and the first and second support parts SUP1 and SUP2 may be separated from each other.

Accordingly, the first rotating parts ROP1 and the second rotating parts ROP2 may be detachably coupled to the first and second support parts SUP1 and SUP2 by the fastening units CU. That is, the first hinge HIG1 and the second hinge HIG2 may each be detachably coupled to the first and second support parts SUP1 and SUP2.

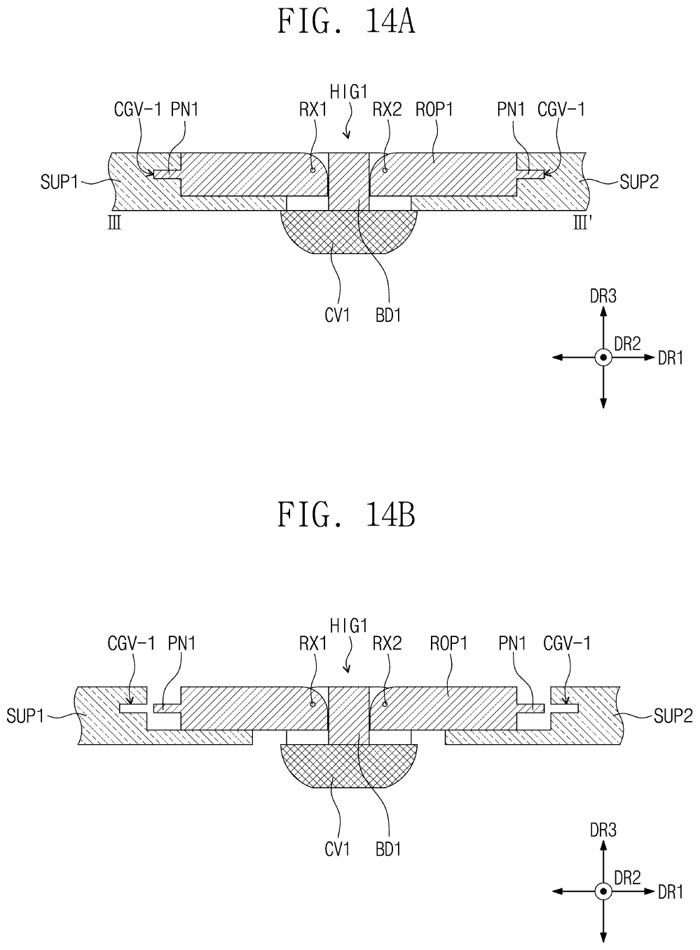

FIGS. 14A and 14B are cross-sectional views taken along line III-III′ illustrated in FIG. 12.

For example, FIG. 14A illustrates a state in which the first and second support parts SUP1 and SUP2 are coupled to the first hinge HIG1, and FIG. 14B illustrates a state in which the first and second support parts SUP1 and SUP2, and the first hinge HIG1 are separated from each other.

Referring to FIGS. 12 and 14A, the first rotating parts ROP1 may be coupled to the first and second support parts SUP1 and SUP2 by the first coupling pins PN1. For example, fastening grooves CGV-1 overlapping the first coupling pins PN1 may be defined on inner side surfaces of the first and second support parts SUP1 and SUP2 having the first recessed portions RES1 defined therein. The first coupling pins PN1 are inserted into the fastening grooves CGV-1 such that the first rotating parts ROP1 may be coupled to the first and second support parts SUP1 and SUP2.

The first coupling pins PN1 may be inserted into the fastening grooves CGV-1 due to an external force. When the diameters of the first coupling pins PN1 are smaller than the diameters of the fastening grooves CGV-1, the first coupling pins PN1 may be easily separated from the first and second support parts SUP1 and SUP2. Accordingly, the diameters of the first coupling pins PN1 may be the same as or slightly greater than the diameters of the fastening grooves CGV-1.

The first hinge HIG1, and the first and second support parts SUP1 and SUP2 may be formed from a plastic material. In this case, when a predetermined external force is applied to the first coupling pins PN1, the first coupling pins PN1 may be forcibly fastened and fixed to the first and second support parts SUP1 and SUP2.

Although not illustrated, the coupling structure of the second hinge HIG2, and the first and second support parts SUP1 and SUP2 may also be the same as or similar to the coupling structure of the first hinge HIG1, and the first and second support parts SUP1 and SUP2. For example, the second coupling pins PN2 of the second hinge HIG2 are inserted into the fastening grooves, which are defined in the first and second support parts SUP1 and SUP2 so as to overlap the second coupling pins PN2, such that the second hinge HIG2, and the first and second support parts SUP1 and SUP2 may be coupled to each other.

Referring to FIGS. 14A and 14B, when the first coupling pins PN1 are separated from the first and second support parts SUP1 and SUP2 due to a predetermined external force, the first rotating parts ROP1 and the first and second support parts SUP1 and SUP2 may be separated from each other.

Although not illustrated, when the second coupling pins PN2 are separated from the first and second support parts SUP1 and SUP2 due to a predetermined external force, the second rotating parts ROP2 and the first and second support parts SUP1 and SUP2 may be separated from each other.

Accordingly, the first rotating parts ROP1 and the second rotating parts ROP2 may be detachably coupled to the first and second support parts SUP1 and SUP2 by the first and second coupling pins PN1 and PN2. That is, the first hinge HIG1 and the second hinge HIG2 may each be detachably coupled to the first and second support parts SUP1 and SUP2.

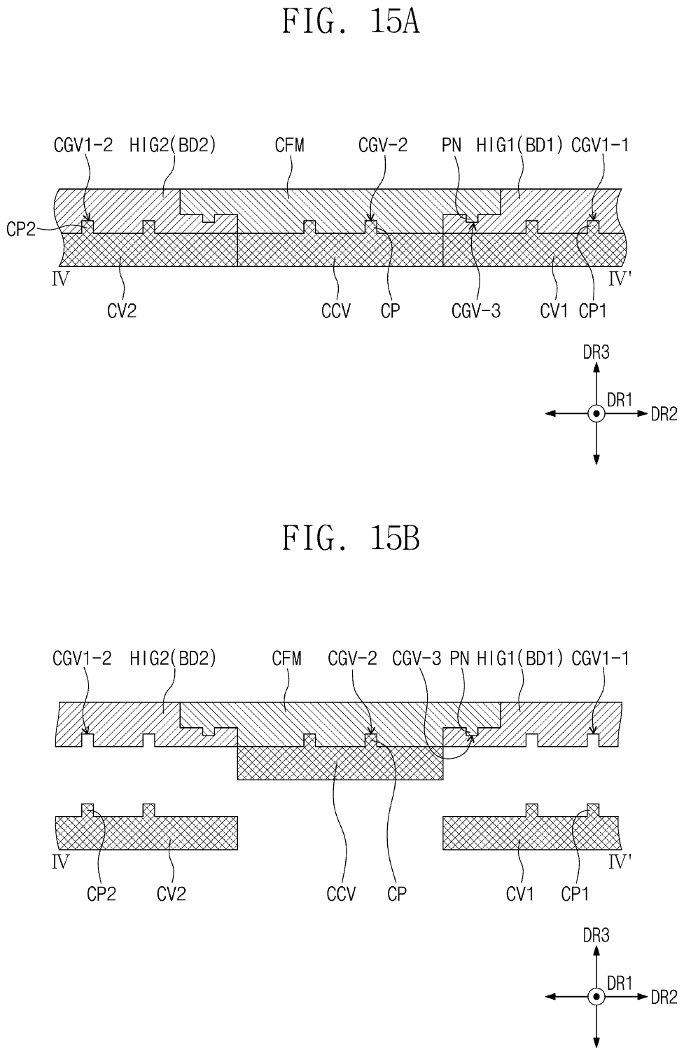

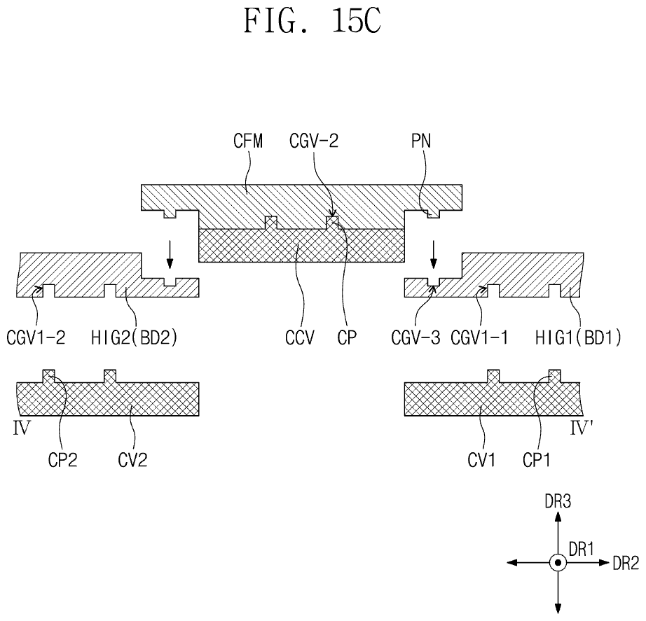

FIGS. 15A, 15B, and 15C are cross-sectional views taken along line IV-IV′ illustrated in FIG. 12.

For example, FIG. 15A illustrates a state in which the first and second hinges HIG1 and HIG2 are coupled to the first and second hinge covers CV1 and CV2, and FIG. 15B illustrates a state in which the first and second hinges HIG1 and HIG2, and the first and second hinge covers CV1 and CV2 are separated from each other. Also, FIG. 15C illustrates a state in which the first and second hinges HIG1 and HIG2 are separated from the central frame CFM.

Referring to FIGS. 12 and 15A, the first and second hinge covers CV1 and CV2 may be coupled to the first and second hinges HIG1 and HIG2. The first coupling pins CP1 are inserted into first fastening grooves CGV1-1, which are defined on a lower surface of the first main body BD1 so as to overlap the first coupling pins CP1 in a plan view in an unfolded state, such that the first hinge cover CV1 may be coupled to the first hinge HIG1. The second coupling pins CP2 are inserted into second fastening grooves CGV1-2, which are defined on a lower surface of the second main body BD2 so as to overlap the second coupling pins CP2 in a plan view in an unfolded state, such that the second hinge cover CV2 may be coupled to the second hinge HIG2.

The central cover CCV may be coupled to the central frame CFM. For example, the coupling pins CP are inserted into fastening grooves CGV-2, which are defined on a lower surface of the central frame CFM so as to overlap the coupling pins CP in a plan view in an unfolded state, such that the central cover CCV may be coupled to the central frame CFM.

The central frame CFM may be coupled to the first and second hinges HIG1 and HIG2. The coupling pins PN may protrude downward from a lower surface of the central frame CFM adjacent to opposite sides of the central cover CCV. The coupling pins PN are inserted into fastening grooves CGV-3, which are defined on the upper surfaces of the first main body BD1 and the second main body BD2 so as to overlap the coupling pins PN in a plan view in an unfolded state, such that the central frame CFM may be coupled to the first and second hinges HIG1 and HIG2.

The structure in which the first and second coupling pins CP1 and CP2, and the coupling pins CP and PN are inserted into the first and second fastening grooves CGV1-1 and CGV1-2, and the fastening grooves CGV-2 and CGV-3 may be the same as or similar to the above-described structure in which the first coupling pins PN1 are inserted into the fastening grooves CGV-1.

Referring to FIGS. 15A and 15B, when the first and second coupling pins CP1 and CP2 are separated from the first and second hinges HIG1 and HIG2 due to a predetermined external force, the first and second hinge covers CV1 and CV2 may be separated from the first and second hinges HIG1 and HIG2.

Accordingly, the first and second hinge covers CV1 and CV2 may be detachably coupled to the first and second hinges HIG1 and HIG2, respectively. The first hinge cover CV1 may be detachably coupled to a rear surface of the first hinge HIG1, and the second hinge cover CV2 may be detachably coupled to a rear surface of the second hinge HIG2. The first hinge cover CV1 may be detachably coupled to the first main body BD1 of the first hinge HIG1. The second hinge cover CV2 may be detachably coupled to the second main body BD2 of the second hinge HIG2.

Referring to FIGS. 15B and 15C, a predetermined external force is applied along a downward direction to the first and second hinges HIG1 and HIG2, and the first and second hinges HIG1 and HIG2 may be separated from the central frame CFM. The first and second hinges HIG1 and HIG2 may be separated from the coupling pins PN. Accordingly, the first and second hinges HIG1 and HIG2 may be detachably coupled to the central frame CFM.

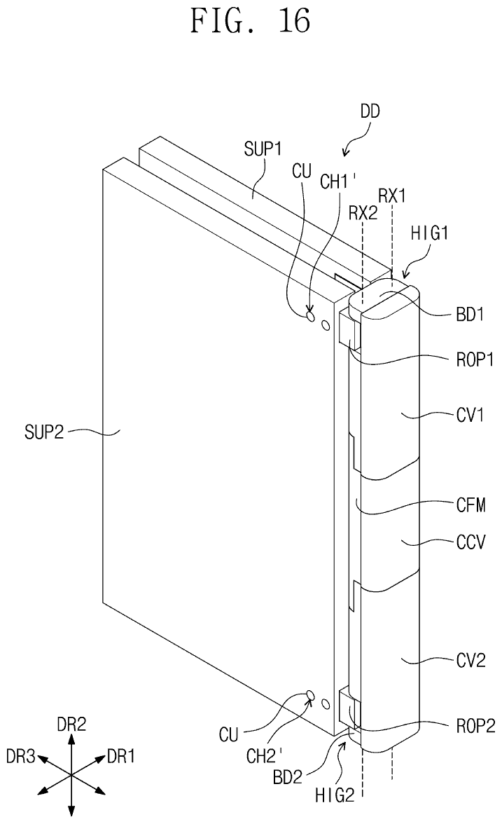

FIGS. 16 to 20 are views for describing a method for repairing a display device according to an embodiment of the invention.

A method for repairing a display device DD is substantially a method for replacing a first hinge HIG1 or a second hinge HIG2, and for example, the display module DM is omitted in FIGS. 16 to 20.

Referring to FIG. 16, the display device DD may be in a folded state. For example, the display device DD may be folded such that the first and second hinges HIG1 and HIG2 rotate first and second support parts SUP1 and SUP2 with respect to first and second rotation axes RX1 and RX2. In the folded state, the third direction DR3 may be defined as a direction perpendicular to a plane including the first and second rotation axes RX1 and RX2.

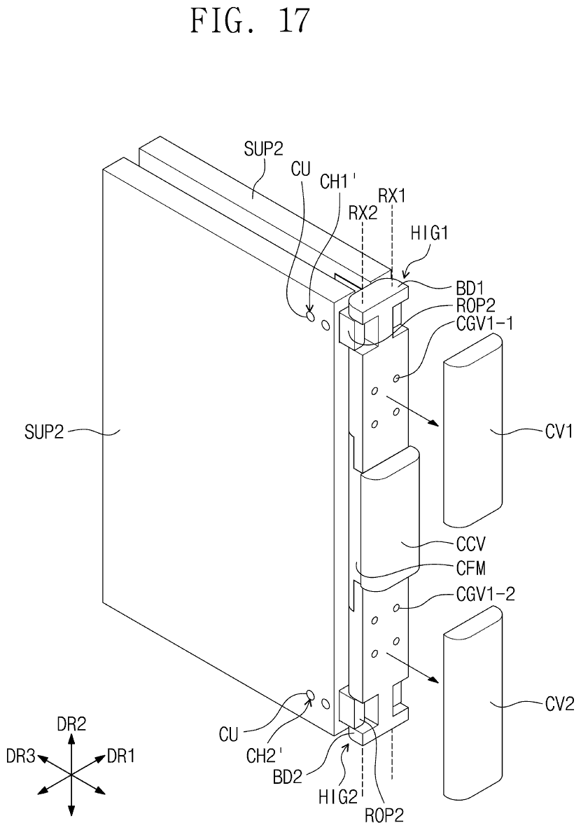

Referring to FIGS. 15B and 17, the first hinge cover CV1 may be separated from the first hinge HIG1. Additionally, the second hinge cover CV2 may also be separated from the second hinge HIG2.

If the folding operation of the display device DD is not performed properly, it may be suspicious whether the first and second hinges HIG1 and HIG2 are defective. That is, the first hinge HIG1 or the second hinge HIG2 of the display device DD may be defective. In order to check whether the first and second hinges HIG1 and HIG2 are defective, it is required to separate the first and second hinge covers CV1 and CV2 covering the first and second hinges HIG1 and HIG2.

In an embodiment of the invention, the first hinge cover CV1 is separated from the first hinge HIG1, and thus it is possible to check whether the first hinge HIG1 is defective. Also, the second hinge cover CV2 is separated from the second hinge HIG2, and thus it is possible to check whether the second hinge HIG2 is defective.

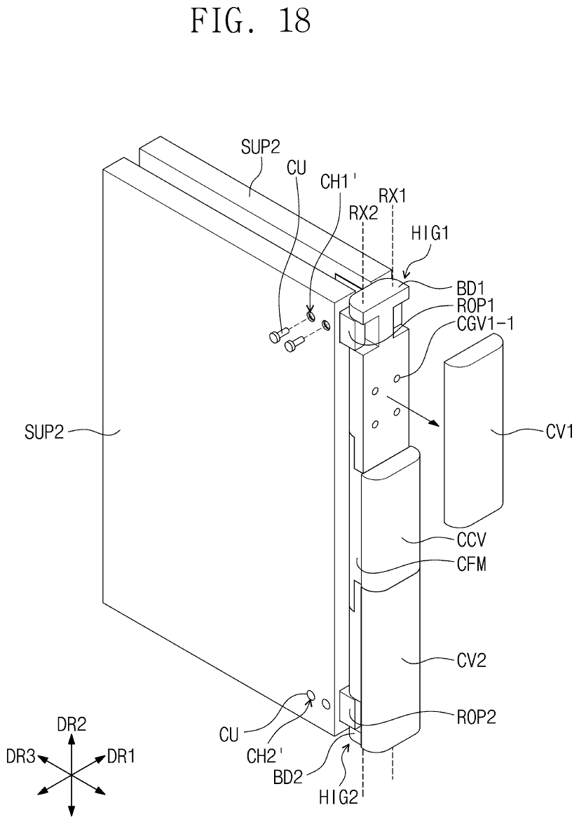

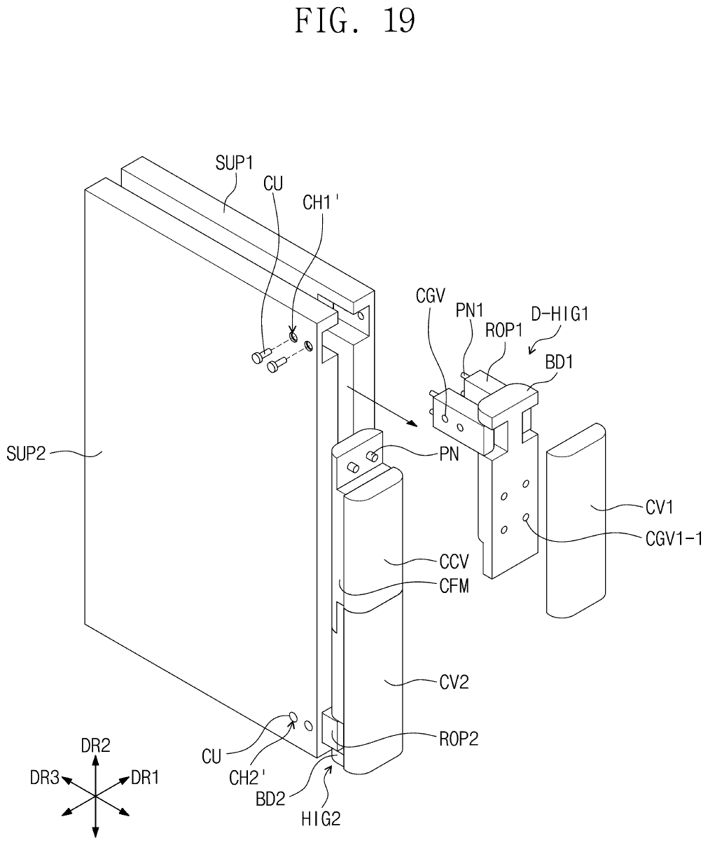

Referring to FIGS. 18 and 19, when a check result shows that the first hinge HIG1 is defective, a defective first hinge D-HIG1 may be separated from the first and second support parts SUP1 and SUP2 in a folded state.

Referring to FIGS. 13B and 18, the fastening units CU may be separated from the first and second support parts SUP1 and SUP2, and the first rotating parts ROP1 to separate the first hinge HIG1 from the first and second support parts SUP1 and SUP2. The central cover CCV does not overlap the first hinge HIG1 in the third direction DR3 so that the first hinge HIG1 can be separated from the first and second support parts SUP1 and SUP2 without separating the central cover CCV.

Referring to FIGS. 14B, 15C, and 19, the first coupling pins PN1 may be separated from the first and second support parts SUP1 and SUP2. Also, the defective first hinge D-HIG1 may be separated from the central frame CFM. According to the above-described operation, the defective first hinge D-HIG1 may be separated from the first and second support parts SUP1 and SUP2.

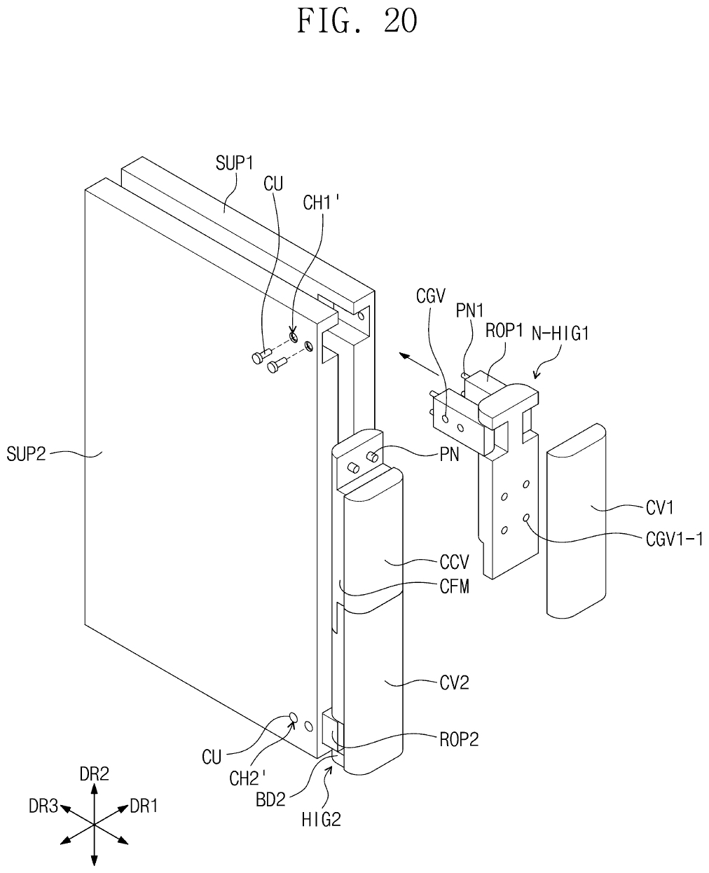

Referring to FIG. 20, a good first hinge N-HIG1 (e.g., non-defective hinge) may be coupled to the first and second support parts SUP1 and SUP2. Thereafter, the first hinge cover CV1 separated from the defective first hinge D-HIG1 may be coupled to a rear surface of the good first hinge N-HIG1.

Although not illustrated, when the second hinge HIG2 is defective, the defective second hinge HIG2 may be replaced with the good second hinge HIG2 in the same manner as the manner of the replacement of the above-described first hinge HIG1.

In an embodiment of the invention, when the first hinge HIG1 or the second hinge HIG2 is defective, it is possible to more easily check defects in the first and second hinges HIG1 and HIG2 by separating only the first and second hinge covers CV1 and CV2 without having to disassemble the entire display device DD. Additionally, when the first hinge HIG1 or the second hinge HIG2 is defective, it is possible to more easily replace a defective hinge without having to disassemble the entire display device DD. Therefore, the display device DD may be more easily repaired.

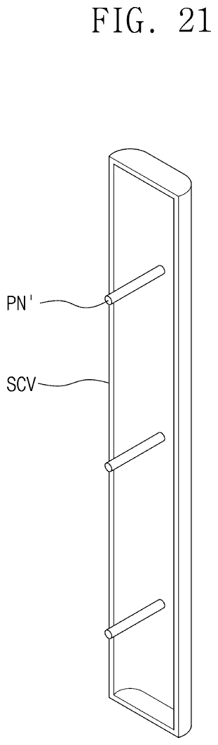

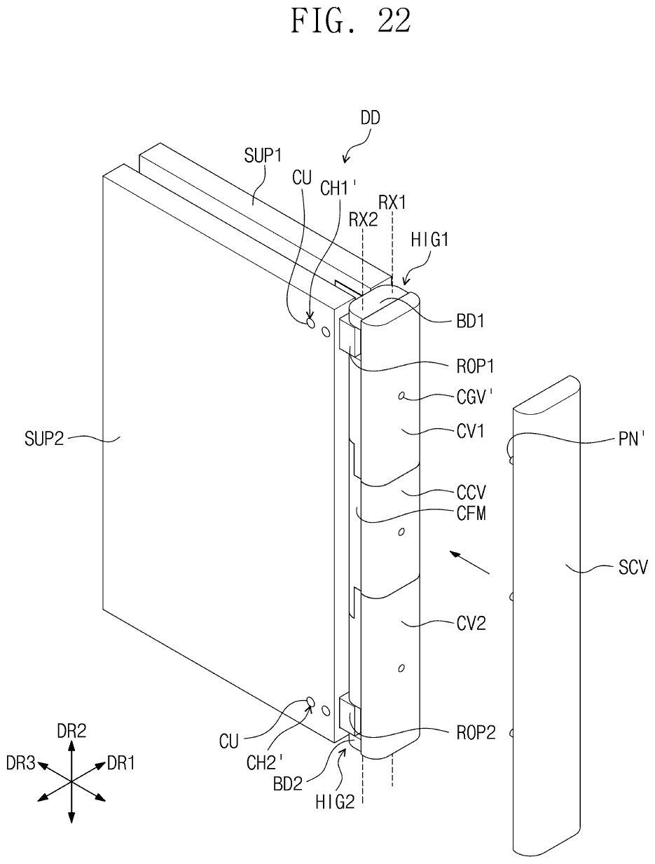

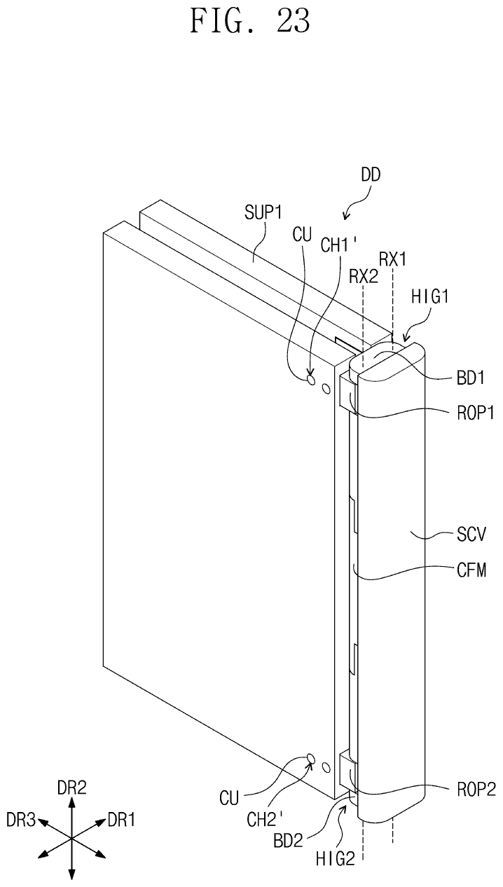

FIG. 21 is a view illustrating an auxiliary cover covering the cover part illustrated in FIG. 12. FIGS. 22 and 23 are views illustrating an auxiliary cover coupled to a cover part.

Referring to FIGS. 12 and 21, an auxiliary cover SCV may be disposed below the cover part CVP. The auxiliary cover SCV may be disposed below the first and second hinge covers CV1 and CV2, and the central cover CCV.

Referring to FIGS. 21, 22, and 23, coupling pins PN′ may protrude from the auxiliary cover SCV toward the cover part CVP. Fastening grooves CGV′ may be defined on rear surfaces of the first and second hinge covers CV1 and CV2, and the central cover CCV which face the auxiliary cover SCV. The fastening grooves CGV′ may overlap the coupling pins PN′.

The coupling pins PN′ are inserted into the fastening grooves CGV′ such that the auxiliary cover SCV may be coupled to the first and second hinge covers CV1 and CV2, and the central cover CCV. The auxiliary cover SCV may cover the first and second hinge covers CV1 and CV2, and the central cover CCV.

When the coupling pins PN′ are separated from the first and second hinge covers CV1 and CV2, and the central cover CCV, the auxiliary cover SCV may be separated from the first and second hinge covers CV1 and CV2, and the central cover CCV. Accordingly, the auxiliary cover SCV may be detachably coupled to the first and second hinge covers CV1 and CV2, and the central cover CCV.

According to an embodiment of the invention, since hinge covers which each cover hinges are separated from the hinges, it is possible to check a defective condition of each of the hinges. A defective hinge is separated from a display device, and then a normal hinge is coupled to the display device. Thereafter, the hinge cover may be re-connected to the normal hinge. Therefore, repair of the display device may be easily performed.

In the above, description has been made with reference to preferred embodiments of the invention, but those skilled in the art or those of ordinary skill in the relevant technical field may understand that various modifications and changes may be made to the invention within the scope not departing from the spirit and the technical scope of the invention described in the claims to be described later. In addition, the embodiments disclosed in the invention are not intended to limit the technical spirit of the invention, and all technical ideas within the scope of the following claims and their equivalents should be construed as being included in the scope of the invention.

What is claimed is:

1. A display device comprising:
a display module including a first non-folding region, a foldable region, and a second non-folding region arranged in a first direction in an unfolded state;
a first support part disposed below the first non-folding region;
a second support part disposed below the second non-folding region;
a plurality of hinges separated from each other, and disposed below the foldable region and between the first support part and the second support part; and
a plurality of hinge covers disposed below the hinges.

2. The display device of claim 1, wherein the hinge covers are separated from each other.

3. The display device of claim 1, wherein the hinge covers are detachably coupled to the corresponding hinges, respectively.

4. The display device of claim 1, wherein the hinges are each detachably coupled to the first and second support parts.

5. The display device of claim 1, wherein the hinge covers are disposed to one-to-one correspond to the hinges, and
wherein the hinges are disposed below the foldable region and define biaxial rotation axes extending parallel to a second direction crossing the first direction.

6. The display device of claim 5, wherein the hinges comprise:
a first hinge; and
a second hinge spaced apart from the first hinge in the second direction and having a shape symmetrical to the first hinge with respect to a plane, which is between the first hinge and the second hinge and parallel to the first direction and perpendicular to the second direction.

7. The display device of claim 6, wherein the hinge covers comprise:
a first hinge cover detachably coupled to a rear surface of the first hinge; and
a second hinge cover detachably coupled to a rear surface of the second hinge.

8. The display device of claim 5, wherein the biaxial rotation axes are defined adjacent to the first support part and the second support part, respectively, and
wherein the hinges are configured to rotate the first support part and the second support part with respect to the biaxial rotation axes such that the display module is folded.

9. The display device of claim 8, wherein when the display module is folded, a defective hinge among the hinges is separated from the first and second support parts.

10. The display device of claim 1, wherein each of the hinges comprise:
a main body; and
a plurality of rotating parts rotatably coupled to the main body and coupled to the first and second support parts.

11. The display device of claim 10, wherein each of the hinge covers is detachably coupled to the main body of a corresponding hinge among the hinges.

12. The display device of claim 10, wherein the rotating parts are detachably coupled to the first and second support parts.

13. The display device of claim 1, further comprising an auxiliary cover disposed below the hinge covers and configured to cover the hinge covers.

14. The display device of claim 13, wherein the auxiliary cover is detachably coupled to the hinge covers.

15. A method for repairing a display device, the method comprising:
preparing a display device which includes a display module including a first non-folding region, a foldable region, and a second non-folding region arranged in a first direction in an unfolded state, a first support part disposed below the first non-folding region, a second support part disposed below the second non-folding region, a plurality of hinges disposed below the foldable region and between the first and second support parts and coupled to the first and second support parts, and a plurality of hinge covers disposed below the hinges and coupled to the hinges;
folding the display device;
separating the hinge covers from the hinges, and checking whether a defective hinge among the hinges exists;
separating the defective hinge from the first and second support parts;
coupling a normal hinge to the first and second support parts; and
coupling a hinge cover separated from the defective hinge among the hinge covers to a rear surface of the normal hinge.

16. The method of claim 15, wherein the hinges are disposed separately from each other, and the hinge covers are disposed separately from each other before the separating of the hinge covers from the hinges.

17. The method of claim 15, wherein the hinge covers are disposed to one-to-one correspond to the hinges before the separating of the hinge covers from the hinges.

18. The display device of claim 15, wherein each of the hinges comprise:
a main body; and
a plurality of rotating parts rotatably coupled to the main body and coupled to the first and second support parts, respectively.

19. The display device of claim 18, wherein each of the hinge covers is detachably coupled to the main body of a corresponding hinge among the hinges, and
the rotating parts are detachably coupled to the first and second support parts.

20. An electronic apparatus for providing an image comprising:
a display device comprising:
a display module including a first non-folding region, a foldable region, and a second non-folding region arranged in a first direction in an unfolded state;
a first support part disposed below the first non-folding region;
a second support part disposed below the second non-folding region;
a plurality of hinges separated from each other, and disposed below the foldable region and between the first support part and the second support part; and
a plurality of hinge covers disposed below the hinges.
